(19) United States
(12) Patent Application Publication
(10) Pub. No.: US 2015/0155200 A1
(43) Pub. Date: Jun. 4, 2015

(54) Process For Forming And Composite Comprising Conducting Paths Comprising Silver

(71) Applicant: Heraeus Precious Metals GmbH & Co. KG, Hanau (DE)

(72) Inventors: Udo Guntermann, Krefeld (DE); Melanie Bawohl, Hanau (DE); Ronny Horvat, Billigheim (DE)

(21) Appl. No.: 14/550,111

(22) Filed: Nov. 21, 2014

(30) Foreign Application Priority Data
Nov. 29, 2013 (EP) 13005577.5

(51) Int. Cl. H01L 21/768; B05D 1/36; C09D 5/24; B05D 3/10

(52) U.S. Cl. CPC H01L 21/76838; B05D 3/101; B05D 3/104; B05D 1/36; C09D 5/24

(57) ABSTRACT

The invention relates generally to a process (100) comprising as process steps:
a) providing a substrate having a substrate surface;
b) providing a first composition, comprising:
   i) SnCl₂, and
   ii) water;
c) providing a second composition, comprising:
   i) sulfuric acid, and
   ii) a reducing agent;
d) providing a third composition, obtainable by mixing:
   i) AgNO₃,
   ii) nitric acid,
   iii) water, and
   iv) NH₃;
e) contacting the substrate surface with the first composition under obtaining an activated substrate surface;
f) contacting the activated substrate surface with the second composition and the third composition, wherein the activated substrate surface has a temperature in a range from about 10 to about 50° C.

The invention further relates to a composite obtainable by the above process; to a composite comprising an Ag-comprising layer; to a composition comprising AgNO₃; and to a use of composition comprising AgNO₃ for forming conducting paths.

The invention relates to a process for forming conducting paths comprising Ag on a substrate; to a composite obtainable by a process for forming conducting paths comprising Ag on a substrate; to a composite comprising an Ag-comprising layer; to a composition comprising Ag—NO₃; and to a use of composition comprising AgNO₃ for forming conducting paths.

In general, three categories of methods for forming conducting paths on substrates known in the prior art can be distinguished. The first category relates to subtractive methods. Therein, typically a metal layer is deposited on the substrate, a photo-resistive layer is patterned by lithography on the metal layer and then the metal layer is etched to form the conducting paths.

The second category relates to additive methods. Therein, typically the conducting paths are printed, e.g. by screen printing, on the substrate. The third category relates to methods combining subtractive and additive method steps. While additive methods are inherently more economic, i.e. need less consumption of materials and less method steps, finer conducting paths can be obtained by subtractive methods. There is a need for electrically conducting patterns on surfaces of plastic substrates. Mechanical, optical as well as electrical properties of plastic substrates, i.e. polymer substrates, are favourable in view of numerous applications, i.e. in the field of semiconductor technologies, such as photovoltaic technologies and OLEDS. Applying conducting paths comprising copper has been known in the prior for a long time. Realising involves demanding or expensive or both additive or subtractive methods. More recently known in the prior art, are methods involving superimposing conductive pastes on substrates in order to form conducting patterns (see for example EP 0 239 901 B1, US 2013/0069014 A1). Such methods are, for example, screen printing and offset printing. These methods come with the limitations typical for additive methods. In addition, the pastes applicable to these printing techniques have to match certain viscosity limitations, i.e. a viscosity above 1 Pa·s is needed in order to obtain good results of printing.

In general, processes for forming conducting paths on substrates known in the prior art show the following disadvantages. Processes for forming conducting paths known in the prior art involve a temperature above a softening temperature of a polymer substrate, e.g. of polyester. Processes for forming conducting paths known in the prior art involve a solvent which could damage a polymer substrate. Processes for forming conducting paths known in the prior art are not capable of providing fine enough conducting paths. Processes for forming conducting paths known in the prior art are expensive or demanding or both. Processes for forming conducting paths known in the prior art put limitations on a wetting angle or a surface tension or both. Processes for forming conducting paths known in the prior art put limitations on a viscosity. Processes for forming conducting paths known in the prior art put limitations on a size of conductive particles. Processes for forming conducting paths known in the prior art are not applicable to a polymer substrate, e.g. to polyester. Processes for forming conducting paths known in the prior art are not applicable to form conducting paths on three-dimensional non-planar substrates. Processes for forming conducting paths known in the prior art result in a too low adhesive strength of the conducting paths on a substrate.

Generally, it is an object of the present invention to at least partly overcome a disadvantage arising form the prior art. It is an object of the invention to provide a process for forming conducting paths on a polymer substrate, e.g. on a polyester substrate. It is an object of the invention to provide a process for forming conducting paths with a reduced line width on a substrate. It is an object of the invention to provide a process for forming conducting paths with a high specific electrical conductivity on a substrate. It is an object of the invention to provide a process for forming conducting paths which are invisible to the naked eye on a substrate. It is an object of the invention to provide a process for forming conducting paths which are mechanically flexible on a substrate. It is an object of the invention to provide a process for forming conducting paths which have a high adhesive strength on a substrate. It is another object of the invention to provide a process for forming conducting paths on a substrate which puts no or less or both limitations on a viscosity. It is another object of the invention to provide a process for forming conducting paths on a substrate which puts no or less or both limitations on a conducting particle size. It is another object of the invention to provide a process for forming conducting paths on a substrate which puts no or less or both limitations on a wetting angle. It is another object of the invention to provide a process for forming conducting paths on a substrate which puts no or less or both limitations on a surface tension. It is an object of the invention to provide a process for forming conducting paths on a substrate involving no heating of the substrate above a softening temperature of a polymer, e.g. polyester. It is an object of the invention to provide a process for forming conducting paths on substrate, wherein a crystallite size of the conducting paths is in the range from about 30 to about 80 nm. It is an object of the invention to provide a process for forming conducting paths on a three-dimensional non-planar substrate. It is another object of the invention to provide a process for forming conducting paths on a substrate having one selected from the group consisting improved mechanical properties, improved optical properties and improved electrical properties or a combination of at least two thereof. A preferred mechanical property is flexibility or plasticity or both. A preferred optical property is transparency or absorption or both. A preferred electrical property is an electrical conductivity. It is another object of the invention to provide a process for forming conducting paths on a substrate involving a higher degree of freedom regarding a design of the substrate. It is another object of the invention to provide an electronic composite comprising a substrate having conducting paths according to any of the above objects. It is another object of the invention to provide an electronic composite, comprising a substrate according to any of the above objects having conducting paths. It is yet another object of the present invention to provide a composition for forming conducting paths according to any of the above objects on a substrate. It is yet another object of the present invention to provide a composition for forming conducting paths on a substrate according to any of the above objects. It is another object of the present invention to provide chemically more stable consumable solutions for forming conducting paths on a substrate. It is another object of the invention to provide a silver layer comprising a silver layer surface having a reduced average roughness. It is another object of the invention to provide a silver layer having a reduced layer thickness. It is another object of the invention to provide a layer sequence comprising a silver layer, wherein the layer sequence has a reduced total thickness. It is another object of the invention to provide conductive paths having a high electrical conductivity, and a reduced line width, and a reduced thickness, and can be superimposed on a substrate at a low temperature.

A contribution to at least one of the above objects is given by the independent claims. The dependent claims provide preferred embodiments of the present invention which also serve the solution of at least one of the above mentioned objects.

A contribution to the solution of at least one of the above objects is made by a process comprising as process steps:
a) providing a substrate having a substrate surface;
b) providing a first composition, comprising:
   i) SnCl₂, and
   ii) water;
c) providing a second composition, comprising:
   i) sulfuric acid, and
   ii) a reducing agent;
d) providing a third composition, obtainable by mixing:
   i) AgNO₃,
   ii) nitric acid,
   iii) water, and
   iv) NH₃;
e) contacting the substrate surface with the first composition under obtaining an activated substrate surface;
f) contacting the activated substrate surface with the second composition and the third composition, wherein the activated substrate surface has a temperature in a range from about 10 to about 50° C.

A preferred water is distilled water. Preferably before contacting the substrate surface with the first composition, the substrate surface is washed with demineralised water. A preferred demineralised water has an electrical conductivity of less than 0.1 μS, preferably less than 0.08 μS, more preferably less than 0.05 μS.

The reducing agent is preferably an organic compound. A preferred reducing agent comprises an aldehyde group, or is capable of forming an aldehyde group in a solution, or both. A preferred reducing agent is a reducing sugar. A preferred reducing sugar is a mono sugar or a poly sugar or both. A preferred mono sugar is one selected from the group consisting of an aldose, an acyloin, glucose, dextrose, galactose and fructose or a combination of at least two thereof. A preferred second composition further comprises a stabilising agent. The stabilising agent stabilises one selected from the group consisting of the first composition, the second composition and the third composition or a combination of at least two thereof. A preferred stabilising agent comprises an aldehyde. A preferred aldehyde is formaldehyde. The formaldehyde preferably stabilises an aqueous solution, comprising a sugar, against biological contamination or growth or both.

For the use throughout this document contacting with a composition can stand for contacting with the single composition, or contacting with a mixture which comprises the composition, or contacting with a mixture obtained by mixing the composition with one or more other compositions. In the latter alternative the mixture may not comprise the original composition but reaction products of the composition and the one or more other compositions.

In an embodiment of the invention the reducing agent is a sugar. A preferred sugar is a poly sugar. A preferred poly sugar is a disaccharide or an oligosaccharide or both. A preferred disaccharide is lactose or maltose or both.

In an embodiment of the invention the first composition comprises Ag in a range of less than 1 wt.-%, preferably less than 0.09 wt.-%, more preferably less than 0.08 wt.-%, most preferably less than 0.05 wt.-%, based on the total weight of the first composition.

In an embodiment of the invention
a) the process comprises as a further process step, providing a fourth composition, comprising
   i) NaOH,
   ii) NH₃, and
   iii) water; and
b) the process step f) further comprises contacting the activated substrate surface with the fourth composition.

In an embodiment of the invention before contacting the substrate surface with the second composition, the third composition and the fourth composition, the third composition and the fourth composition are mixed. Preferably the third composition and the fourth composition are mixed 24 h, more preferably 5 h, most preferably 30 min, before contacting the substrate surface with the second composition, the third composition and the fourth composition.

In an embodiment of the invention one selected from the group consisting of the first composition, the second composition, the third composition and the fourth composition or a combination of at least two thereof comprises further cations other than the present cations of each of the group consisting of Sn, Na and Ag in a range of less than 1 ppmw, preferably less than 0.9 ppmw, more preferably 0.08 ppmw, most preferably less than 0.05 ppmw, based on the total weight of the composition characterised by this feature.

In an embodiment of the invention less than 30 s, preferably less than 20 s, more preferably less than 10 s, more preferably less than 5 s, more preferably less than 3 s, even more preferably less than 2 s, most preferably less than 1 s, before contacting the substrate surface with the second composition and the third composition and optionally the fourth composition; the second composition and the third composition and optionally the fourth composition are mixed. Preferably, the second composition and the third composition and optionally the fourth composition are mixed by a nozzle. A preferred nozzle is a multi-fluid nozzle. In a preferred mixing by a multi-fluid nozzle the second composition and the third composition and optionally the fourth composition are mixed outside of the multi-fluid nozzle.

In an embodiment of the invention the substrate according to the process comprises one selected from the group consisting of a polymer, a ceramic, a semiconductor, a stone and a glass or a combination of at least two thereof. A preferred substrate comprises a polymer. A preferred substrate comprising a polymer is an ABS plastic substrate.

In an embodiment of the invention the polymer according to the process is one selected from the group consisting of a polyimide, a polyester, PEDOT:PSS, polyacetylene, polyphenylene vinylene, polypyrrole, polythiophene, polyaniline and polyphenylene sulfide or a combination of at least two thereof. A preferred polymer is polyester or PEDOT:PSS or both.

In an embodiment of the invention a first layer is obtained by the process, wherein the first layer
a) superimposes the substrate surface,
b) comprises Ag, and
c) comprises a first layer surface.

A preferred first layer is electrically conductive.

In an embodiment of the invention the first layer according to the process has a layer thickness which is described by a non-constant function of the position on the substrate surface.

In an embodiment of the invention the first layer has a layer thickness in a range from about 10 nm to about 100 μm, preferably in a range from about 15 nm to about 10 μm, more preferably in a range from about 20 nm to about 5 μm, more preferably in a range from about 20 nm to about 3 μm, more preferably in a range from about 20 nm to about 2 μm, more preferably in a range from about 20 nm to about 1 μm, more preferably in a range from about 20 nm to about 500 nm, more preferably in a range from about 20 nm to about 450 nm, even more preferably in a range from about 20 nm to about 400 nm, most preferably in a range from about 20 nm to about 100 nm.

In an embodiment of the invention the first layer according to the process comprises a protruding region having a width in a range from about 5 to about 100 μm, preferably in a range from about 10 to about 80 μm, more preferably in a range from about 20 to about 70 μm, most preferably in a range from about 30 to about 60 μm.

In an embodiment of the invention the first layer surface according to the process has a surface resistivity of less than 10 Ω/sq, preferably less than 7 Ω/sq, more preferably less than 5 Ω/sq, most preferably less than 1 Ω/sq.

In an embodiment of the invention a further process step comprises superimposing the first layer surface by a further layer. A preferred superimposing is one selected from the group consisting of a spraying, a printing, a dipping, a brush coating, a laminating, a slot die coating and a curtain coating or a combination of at least two thereof. A preferred printing is one selected from the group consisting of inkjet printing, tampon printing, offset printing, screen printing, gravure printing and flexographic printing or a combination of at least two thereof. A preferred further layer is a varnish layer. A preferred varnish layer is one selected from the group consisting of a protective varnish layer, a nano varnish layer and a UV absorbing varnish layer or a combination of at least two thereof. Preferably, a nano varnish increases a scratch resistance. Another preferred further layer comprises an additive. A preferred additive is a pigment. Another preferred further layer is dried at a temperature in a range from about 20 to about 90° C., preferably in a range from about 30 to about 80° C., more preferably in a range from about 40 to about 70° C., most preferably in a range from 55 to about 65° C., after superimposing the further layer on the first layer surface.

In an embodiment of the invention the further layer according to the process is electrically conductive or transparent or both.

In an embodiment of the invention the further layer according to the process comprises an electrically conductive polymer.

In an embodiment of the invention the electrically conductive polymer according to the process is one selected from the group consisting of PEDOT:PSS, polyacetylene, polyphenylene vinylene, polypyrrole, polythiophene, polyaniline and polyphenylene sulfide or a combination of at least two thereof. A preferred electrically conductive polymer is PEDOT:PSS.

In an embodiment of the invention at least one of the contactings is one selected from the group consisting of a spraying, a printing, a transfer and an extrusion or a combination of at least two thereof. The transfer is performed by: providing a transfer substrate having a transfer substrate surface, wherein the transfer substrate surface is superimposed by a layer which is to be transferred; placing the transfer substrate on the substrate, wherein the transfer substrate surface faces the substrate surface; applying pressure or heat or both to at least a part of the transfer substrate. Preferred means of applying pressure to the transfer substrate are rubbing or pressing or both. A preferred heating of the transfer substrate is one selected from the group consisting of a heating in an oven, a heating by an IR-source and a heating by a laser beam or a combination of at least two thereof. It is also possible to detach the layer which is to be transferred from the transfer substrate by floating the layer onto the surface of a liquid (e.g. water) where it is picked up and placed on the substrate surface, or by immersing the transfer substrate with the layer which is to be transferred into the liquid and detaching the layer by removing the transfer substrate from the liquid. The above described transfer is known as decalcomania. A preferred spraying is a spraying through a mask or a spraying by a multi-fluid nozzle or both. A preferred printing is one selected from the group consisting of a screen printing, an inkjet printing, an offset printing, a tampon printing, a gravure printing and a flexographic printing or a combination of at least two thereof.

In an embodiment of the invention the substrate according to the process is comprised by one selected from the group consisting of a plate, a film, a membrane, a fibre, a fabric, a ribbon and a composite or a combination of at least two thereof. A preferred fabric is a woven fabric or a non-woven fabric or both.

In an embodiment of the invention the composite according to the process is an electronic composite or a decorative composite or both.

In an embodiment of the invention the electronic composite according to the process is one selected from the group consisting of a touch panel, an OLED, an EMI shielding, a photovoltais device, a display, and a capacitor or a combination of at least two thereof. A preferred photovoltaic composite is a one selected from the group consisting of photovoltaic cell, a photovoltaic module and a photovoltaic panel or a combination of at least two thereof. A preferred display is an LCD or a plasma display panel or both.

In an embodiment of the invention the decorative composite according to the process is one selected from the group consisting of a ceramic article, a porcelain article, a glass article and a stone or a combination of at least two thereof. A preferred stone is a natural stone or an artificial stone or both. A preferred ceramic article is a table ware or a tile or both. A preferred porcelain article is a table ware or a tile or both. A preferred glass article is a table ware or a tile or both.

In an embodiment of the invention the first composition comprises
a) SnCl₂ in a range from about 0.01 to about 1 wt.-%, preferably in a range from about 0.05 to about 0.5 wt.-%, more preferably in a range from about 0.07 to about 0.4 wt.-%, most preferably in a range from about 0.1 to about 0.25 wt.-%, and
b) water in a range from about 90 wt.-% to the remainder completing the sum of all components of the first composition to 100 wt.-%, preferably in a range from about 92 wt.-% to the remainder completing the sum of all components of the first composition to 100 wt.-%, more preferably in a range from about 94 wt.-% to the remainder completing the sum of all components of the first composition to 100 wt.-%, most preferably in a range from about 96 wt.-% to the remainder completing the sum of all components of the first composition to 100 wt.-%,
   each based on the total weight of the first composition and all contents in wt.-% adding to 100 wt.-%.

In an embodiment of the invention the second composition comprises
a) dextrose in a range from about 60 wt.-% to the remainder completing the sum of all components of the second composition to 100 wt.-%, preferably in a range from about 65 wt.-% to the remainder completing the sum of all components of the second composition to 100 wt.-%, more preferably in a range from about 67 wt.-% to the remainder completing the sum of all components of the second composition to 100 wt.-%, most preferably in a range from about 70 wt.-% to the remainder completing the sum of all components of the second composition to 100 wt.-%,
b) sulfuric acid in a range from about 10 to about 30 wt.-%, preferably in a range from about 12 to about 27 wt.-%, more preferably in a range from about 15 to about 25 wt.-%, most preferably in a range from about 17 to about 22 wt.-%, and
c) formaldehyde in a range from about 3 to about 15 wt.-%, preferably in a range from about 4 to about 13 wt.-%, more preferably in a range from about 5 to about 11 wt.-%, most preferably in a range from about 6 to about 10 wt.-%,
   each based on the weight of the second composition excluding water and all contents in wt.-% adding to 100 wt.-%.

In an embodiment of the invention the third composition is obtainable by mixing
a) AgNO₃ in a range from about 95 wt.-% to the remainder completing the sum of all components of the third composition to 100 wt.-%, preferably in a range from about 96 to the remainder completing the sum of all components of the third composition to 100 wt.-%, more preferably in a range from about 97 to the remainder completing the sum of all components of the third composition to 100 wt.-%, most preferably in a range from about 98 to the remainder completing the sum of all components of the third composition to 100 wt.-%,
b) nitric acid in a range from about 0.5 to about 5 wt.-%, preferably in a range from about 0.75 to about 3 wt.-%, more preferably in a range from about 1 to about 2 wt.-%, most preferably in a range from about 1.1 to about 1.6 wt.-%, and
c) NH₃ in a range from about 0.01 to about 0.1 wt.-%, preferably in a range from about 0.01 to about 0.08 wt.-%, more preferably in a range from about 0.01 to about 0.06 wt.-%, most preferably in a range from about 0.01 to about 0.04 wt.-%,
   each based on the weight of the third composition excluding water and all contents in wt.-% adding to 100 wt.-%.

In an embodiment of the invention the fourth composition comprises
a) NaOH in a range from about 99 wt.-% to the remainder completing the sum of all components of the fourth composition to 100 wt.-%, preferably in a range from about 99.3 to the remainder completing the sum of all components of the fourth composition to 100 wt.-%, more preferably in a range from 99.5 to the remainder completing the sum of all components of the fourth composition to 100 wt.-%, most preferably in a range from 99.8 to the remainder completing the sum of all components of the fourth composition to 100 wt.-%, and
b) NH₃ in a range from about 0.01 to about 1 wt.-%, preferably in a range from about 0.01 to about 0.7 wt.-%, more preferably in a range from about 0.01 to about 0.5 wt.-%, most preferably in a range from about 0.01 to about 0.2 wt.-%,
   each based on the weight of the fourth composition excluding water and all contents in wt.-% adding to 100 wt.-%.

A contribution to the solution of at least one of the above objects is made by a composite obtainable by the process according to the invention.

In an embodiment of the invention the composite is an electronic composite or a decorative composite or both. A preferred electronic composite is one selected from the group consisting of a touch panel, an OLED, an EMI shielding, a photovoltaic composite, a display, and a capacitor or a combination of at least two thereof. A preferred photovoltaic composite is a one selected from the group consisting of photovoltaic cell, a photovoltaic module and a photovoltaic panel or a combination of at least two thereof. A preferred display is an LCD or a plasma display panel or both. A preferred decorative composite is one selected from the group consisting of a ceramic article, a porcelain article, a glass article and a stone or a combination of at least two thereof. A preferred stone is a natural stone or an artificial stone or both. A preferred ceramic article is a table ware or a tile or both. A preferred porcelain article is a table ware or a tile or both. A preferred glass article is a table ware or a tile or both.

A contribution to the solution of at least one of the above objects is made by a composite, comprising a layer sequence, wherein the layer sequence comprises as layers:
a) a substrate having a substrate surface;
b) a first layer having a first layer surface,
   wherein the first layer
      i) superimposes the substrate surface,
      i) comprises Ag,
      ii) fulfils at least one, preferably at least two, and more preferably all, of the following criteria
         A. the first layer comprises a crystallite having a crystallite size in a range from about 10 to about 160 nm, preferably in a range from about 15 to about 130 nm, more preferably in a range from about 20 to about 100 nm, most preferably in a range from about 30 to about 80 nm,
         B. the first layer has a surface resistivity of less than 10 Ω/sq, preferably less than 7 Ω/sq, more preferably less than 5 Ω/sq, most preferably less than 1 Ω/sq,
         C. the first layer has a layer thickness in a range from about 10 nm to about 10 μm, preferably in a range from about 20 nm to about 5 μm, more preferably in a range from about 30 nm to about 3 μm, more preferably in a range from about 40 nm to about 2 μm, more preferably in a range from about 50 nm to about 1 μm, more preferably in a range from about 100 nm to about 500 nm, even more preferably in a range from about 200 nm to about 450 nm, most preferably in a range from about 250 nm to about 400 nm,
         D. the first layer has a gloss in a range from about 500 to about 2000 GU, preferably in a range from about 700 to about 1900 GU, more preferably in a range from about 1000 to about 1800 GU, most preferably in a range from about 1500 to about 1700 GU, and
         E. the first layer has an average roughness in a range from about 1 to about 500 nm, preferably in a range from about 1 to about 100 nm, more preferably in a range from about 3 to about 50 nm, most preferably in a range from about 5 to about 10 nm,
      or a combination of at least two or more thereof.

Preferably, the first layer fulfils at least one of the following combinations of the above criteria: ABCDE, ABCD, ACE, AB, BC, BD, BCD, CD and ABE.

In an embodiment of the invention the substrate according to the composite is comprised by one selected from the group consisting of a plate, a film, a membrane, a fibre, a fabric and a ribbon or a combination of at least two thereof. A preferred fabric is a woven fabric or a non-woven fabric or both.

In an embodiment of the invention the composite is an electronic composite or a decorative composite or both.

In an embodiment of the invention the electronic composite according to the composite is one selected from the group consisting of a touch panel, an OLED, an EMI shielding, a photovoltaic device, a display, and a capacitor or a combination of at least two thereof. A preferred photovoltaic composite is a one selected from the group consisting of photovoltaic cell, a photovoltaic module and a photovoltaic panel or a combination of at least two thereof. A preferred display is an LCD or a plasma display panel or both.

In an embodiment of the invention the decorative composite according to the composite is one selected from the group consisting of a ceramic article, a porcelain article, a glass article and a stone or a combination of at least two thereof. A preferred stone is a natural stone or an artificial stone or both. A preferred ceramic article is a table ware or a tile or both. A preferred porcelain article is a table ware or a tile or both. A preferred glass article is a table ware or a tile or both.

In an embodiment of the invention the substrate according to the composite comprises one selected from the group consisting of a polymer, a ceramic, a semiconductor, a stone and a glass or a combination of at least two thereof.

In an embodiment of the invention the polymer according to the composite is one selected from the group consisting of a polyimide, a polyester, PEDOT:PSS, polyacetylene, polyphenylene vinylene, polypyrrole, polythiophene, polyaniline and polyphenylene sulfide or a combination of at least two thereof. A preferred polymer is polyester or PEDOT:PSS or both.

In an embodiment of the invention the layer sequence comprises a further layer, wherein the further layer superimposes the first layer surface. A preferred further layer is a protective varnish layer. Another preferred further layer comprises an additive. A preferred additive is a pigment. Another preferred layer is a nano varnish or a UV absorbing varnish or both. Preferably, a nano varnish increases a scratch resistance.

In an embodiment of the invention the further layer according to the composite is transparent or electrically conductive or both.

In an embodiment of the invention the further layer according to the composite comprises an electrically conductive polymer.

In an embodiment of the invention the electrically conductive polymer according to the composite is one selected from the group consisting of PEDOT:PSS, polyacetylene, polyphenylene vinylene, polypyrrole, polythiophene, polyaniline and polyphenylene sulfide or a combination of at least two thereof. A preferred electrically conductive polymer is PEDOT:PSS.

In an embodiment of the invention the layer sequence is bendable.

In an embodiment of the invention the further layer has a layer thickness in a range from about 5 to about 350 μm, preferably in a range from about 5 to about 300 μm, more preferably in a range from about 10 to about 100 μm, most preferably in a range from about 20 to about 50 μM.

In an embodiment of the invention the first layer according to the composite has a layer thickness which is described by a non-constant function of the position on the substrate surface.

In an embodiment of the invention the first layer comprises a protruding region having a width in a range from about 5 to about 100 μm, preferably in a range from about 10 to about 80 μm, more preferably in a range from about 20 to about 70 μm, most preferably in a range from about 30 to about 60 μm.

A contribution to the solution of at least one of the above objects is made by a composition obtainable by mixing
a) an aldehyde,
b) sulfuric acid,
c) a further organic compound,
d) AgNO₃,
e) nitric acid,
f) water,
g) NH3, and
h) NaOH.

A preferred further organic compound is a sugar. A preferred sugar is a poly sugar.

A contribution to the solution of at least one of the above objects is made a use of the composition according to the invention for superimposing conducting paths on a substrate surface of a substrate.

### First Layer

A preferred first layer is structured. A preferred structured first layer is a relief. A preferred relief comprises a protruding region. A preferred protruding region is laterally curved or laterally linear or both. Another preferred protruding region is a conducting path. A preferred first layer comprises a conducting path. For the use throughout this document a protruding region is a laterally limited region of the first layer wherein the laterally limited region has a thickness which is at least twice as high as a highest thickness of regions of the first layer which are adjacent to the laterally limited region. Therein the highest thickness of regions of the first layer which are adjacent to the laterally limited region can be zero or larger than zero.

### Bendable

For the use throughout this document a layer or the layer sequence are bendable if an angle between a first tangent on a surface of the layer or the layer sequence and a further tangent on the surface of the layer or the layer sequence can be mechanically varied by at least 10°, preferably by at least 15°, more preferably by at least 20°, more preferably by at least 25°, more preferably by at least 30°, more preferably by at least 35°, more preferably by at least 40°, more preferably by at least 45°, more preferably by at least 50°, more preferably by at least 60°, more preferably by at least 70°, more preferably by at least 80°, even more preferably by at least 90°, most preferably by at least 100°, without destroying the layer or a layer of the layer sequence.

### Multi-Fluid Nozzle

A multi-fluid nozzle is a nozzle which is designed to emit more than one fluids, which are fed into the multi-fluid nozzle, simultaneously. A preferred multi-fluid nozzle emits the more than one fluids without mixing the more than one fluids with each other inside of the multi-fluid nozzle. A preferred emitting is a spraying. A preferred multi-fluid nozzle is one selected from the group consisting of a two-fluid nozzle, a three-fluid-nozzle, a four-fluid nozzle, a five-fluid nozzle and a six-fluid nozzle or a combination of at least two thereof. Another preferred multi-fluid nozzle is designed to emit more than six fluids, which are fed into the multi-fluid nozzle, simultaneously. Therein a fluid can be a liquid or a gas or both. Another preferred multi-fluid nozzle is designed to emit a gas and a liquid simultaneously. Another preferred multi-fluid nozzle emits more than one fluids simultaneously, each from a different orifice. Another preferred multi-fluid nozzle emits more than one fluid simultaneously in such a way that the regions in space into which the fluids are emitted overlap at a certain distance from the multi-fluid nozzle.

### Polymer

A preferred polymer according to the invention is a polymer selected from the group consisting of a homo polymer, a co-polymer, a block co-polymer comprising at least two different monomeric units, a polymer blend comprising at least two polymers, a dendritic polymer, an isolating polymer, a conductive polymer and a semiconductive polymer or a combination of at least two thereof.

### Electronic Composite

A capacitor according to the electronic composite according to the invention, or obtainable by the process according to the invention, or both comprises a layer sequence comprising as layers of the layer sequence: a wave metal layer, comprising a wave metal and a wave metal layer surface; an oxide layer, superimposing the wave metal layer surface, and comprising a wave metal oxide and an oxide layer surface; a substrate according to the invention, superimposing the wave metal layer surface, and comprising an electrically conductive polymer; and a first layer according to the invention. A preferred wave metal is tantalum. A preferred electrically conductive polymer is PEDOT:PSS.

A touch panel according to the electronic composite according to the invention, or obtainable by the process according to the invention, or both comprises a layer sequence comprising as layers of the layer sequence: a substrate layer, comprising a substrate layer surface and a thermoplastic polymer such as PET; a first touch panel layer comprising a conductive polymer such as PEDOT, preferably PEDOT:PSS, superimposing the substrate layer surface, and comprising a first touch panel layer surface and a first conductive pattern; a first layer, superimposing the first touch panel layer surface, and comprising a first layer surface and Ag; a further layer, superimposing the first layer surface, and comprising a further layer surface and an optically transparent adhesive; a further touch panel layer, superimposing the further layer surface, and comprising a conductive polymer such as PEDOT, preferably PEDOT:PSS, a further touch panel layer surface and a further conductive pattern; a further first layer, superimposing the further touch panel layer surface, and comprising a further first layer surface and Ag (preferably showing at least one of the properties of the first layer according to the invention); a polymer layer, superimposing the further first layer surface, and comprising a thermoplastic polymer such as PET. A preferred first touch panel layer is a receive layer or a transmit layer or both. A preferred further touch panel layer is a receive layer or a transmit layer or both. The receive layer and the transmit layer preferably form the conductive pattern which is preferably a web.

An OLED according to the electronic composite according to the invention, or obtainable by the process according to the invention, or both comprises a layer sequence comprising as layers of the layer sequence: a substrate layer, comprising a substrate layer surface; a first layer, superimposing the substrate layer surface, and comprising Ag; a further layer, superimposing the first layer surface, and comprising a further layer surface and a conductive polymer such as PEDOT, preferably PEDOT:PSS. A preferred OLED further comprises as layers of the layer sequence: a hole transport layer, superimposing the further layer surface, and comprising a hole transport layer surface; an emission layer, superimposing the hole transport layer surface, and comprising a emission layer surface; an electron transport layer, superimposing the emission layer surface, and comprising a electron transport layer surface; a cathode layer, superimposing the electron transport layer surface. A preferred substrate layer of an OLED according to the invention comprises glass.

An EMI shielding according to the electronic composite according to the invention, or obtainable by the process according to the invention, or both comprises a layer sequence comprising as layers of the layer sequence: a substrate layer, comprising a substrate layer surface; a first layer, superimposing the substrate layer surface, and comprising Ag.

A preferred photovoltaic cell according to the electronic composite according to the invention, or obtainable by the process according to the invention, or both is an organic solar cell. A preferred organic solar cell has a normal geometry or an inverted geometry or both.

An organic solar cell having a normal geometry comprises a layer sequence comprising as layers of the layer sequence: a substrate layer, comprising a substrate layer surface; a first layer, superimposing the substrate layer surface, and comprising a first layer surface and Ag; a conductive polymer layer, superimposing the first layer surface, and comprising a conductive polymer such as PEDOT, preferably PEDOT:PSS and a conductive polymer layer surface; an organic layer superimposing the conductive polymer layer surface, and comprising an organic layer surface, and preferably comprising conjugated organic molecules; an electron transport layer, superimposing the organic layer surface, and comprising an electron transport layer surface; and a metal layer, superimposing the electron transport layer surface, and comprising a metal.

A preferred organic solar cell having an inverted geometry comprises a non-structured first layer. An organic solar cell having an inverted geometry comprising a non-structured first layer comprises a layer sequence comprising as layers of the layer sequence: a substrate layer, comprising a substrate layer surface; a transparent conductor layer, superimposing the substrate layer surface, and comprising a transparent conductor layer surface and a transparent conductor; an electron transport layer, superimposing the transparent conductor layer surface, and comprising an electron transport layer surface; an organic layer, superimposing the electron transport layer surface, and comprising an organic layer surface, and preferably comprising conjugated organic molecules; a hole transport layer, superimposing the organic layer surface, and comprising a hole transport layer surface; a first layer, superimposing the hole transport layer surface, and comprising Ag.

A preferred non-structured first layer is a positive electrode. An organic solar cell having an inverted geometry comprising a structured first layer comprises a layer sequence comprising as layers of the layer sequence: a substrate layer, comprising a substrate layer surface; a first layer, superimposing the substrate layer surface, and comprising a first layer surface and Ag; a conductive polymer layer, superimposing the first layer surface, and comprising a conductive polymer layer surface and a conductive polymer such as PEDOT, preferably PEDOT:PSS; an electron transport layer, superimposing the conductive polymer layer surface, and comprising an electron transport layer surface; an active layer, superimposing the electron transport layer surface, and comprising an organic layer surface, and preferably comprising conjugated organis molecules; a hole transport layer, superimposing the organic layer surface, and comprising a hole transport layer surface. A preferred layer sequence of an organic solar cell having an inverted geometry and comprising a structured first layer further comprises as a layer a further first layer, superimposing the hole transport layer surface, and comprising Ag. A preferred further first layer is structured. A preferred structured first layer is a negative electrode. A preferred structured further first layer is a positive electrode.

### Preferred Processes

In a preferred process according to the invention only a part of the substrate surface is contacted with the first composition under obtaining the activated substrate surface which is a part of the substrate surface. Preferably, the part of the substrate surface is contacted with the first composition by printing or spraying. A preferred printing is one selected from the group consisting of inkjet printing, tampon printing, offset printing, gravure printing and flexographic printing or a combination of at least two thereof. A preferred spraying is a spraying through a mask. A preferred substrate is bendable. Another preferred substrate is not bendable. Preferably, the part of the substrate surface of the bendable substrate is contacted with the first composition by one selected from the group consisting of inkjet printing, tampon printing and spraying through a mask or a combination of at least two thereof. Preferably, the part of the substrate surface of the substrate, which is not bendable, is contacted with the first composition by one selected from the group consisting of inkjet printing, offset printing, gravure printing, flexographic printing and spraying through a mask or a combination of at least two thereof. Preferably, during contacting the part of the substrate surface with the first composition a part of the substrate surface, which is not to be contacted with the first composition is covered by a mask. Preferably, contacting the activated substrate surface with the second composition and the third composition and optionally the fourth composition is a spraying the second composition and the third composition and optionally the fourth composition onto the activated substrate surface. A preferred spraying the second composition and the third composition and optionally the fourth composition onto the activated substrate surface is a spraying with a two fluid nozzle. Preferably, the substrate surface is washed after contacting the activated substrate surface with the second composition and the third composition and optionally the fourth composition. A preferred washing is a washing with water. Preferably, after washing the substrate, the substrate is dried.

In another preferred process according to the invention the substrate surface is contacted with the first composition under obtaining the activated substrate surface by spraying the substrate surface with the first composition. Preferably, contacting the activated substrate surface with the second composition and the third composition and optionally the fourth composition is a spraying the second composition and the third composition and optionally the fourth composition onto the activated substrate surface. A preferred spraying the second composition and the third composition and optionally the fourth composition onto the activated substrate surface is a spraying with a two fluid nozzle. Preferably, after contacting the activated substrate surface with the second composition and the third composition and optionally the fourth composition, the first layer is partly ablated. Preferably, after contacting the activated substrate surface with the second composition and the third composition and optionally the fourth composition, the first layer is contacted with a photo resist under obtaining a photo resist layer superimposing the first layer surface. Preferably, after contacting the first layer with the photo resist, the photo resist layer is photo structured. A preferred photo structuring is a partly illuminating. Preferably, after photo structuring the photo resist layer, the photo resist layer is developed. A preferred developing the photo resist layer comprises a dissolving a part of the photo resist layer. Preferably, after developing the photo resist layer, the first layer is etched. A preferred etching is a physical etching or a chemical etching or both. A preferred physical etching is a plasma etching or an ion etching or both. A preferred chemical etching is an etching by an etching solution. Preferably, after etching the first layer, the photo resist layer is removed. A preferred removing the photo resist layer is a stripping the photo resist layer.

In another preferred process according to the invention a part of the substrate surface is superimposed by a non-adhesive layer. A preferred superimposing the part the substrate surface by a non-adhesive layer is a printing or a spraying or both. A preferred printing is one selected from the group consisting of inkjet printing, tampon printing, offset printing, gravure printing and flexographic printing or a combination of at least two thereof. A preferred spraying is a spraying through a mask. A preferred substrate is bendable. Another preferred substrate is not bendable. Preferably, the part of the substrate surface of the bendable substrate is superimposed by the non-adhesive layer by one selected from the group consisting of inkjet printing, tampon printing and spraying through a mask or a combination of at least two thereof. Preferably, the part of the substrate surface of the substrate, which is not bendable, is superimposed by the non-adhesive layer by one selected from the group consisting of inkjet printing, offset printing, gravure printing, flexographic printing and spraying through a mask or a combination of at least two thereof. Preferably, during superimposing the part of the substrate surface with the non-adhesive layer a part of the substrate surface, which is not to be superimposed by the non-adhesive layer, is covered by a mask. Preferably, after superimposing the part of the substrate surface by the non-adhesive layer, the substrate surface is contacted with the first composition under obtaining the activated substrate surface which is a part of the substrate surface. A preferred contacting the substrate surface with the first composition is a spraying. Preferably, after contacting the substrate surface with the first composition, the activated substrate surface is contacted with the second composition and the third composition and optionally the fourth composition. A preferred contacting the activated substrate surface with the second composition and the third composition and optionally the fourth composition is a spraying the second composition and the third composition and optionally the fourth composition onto the activated substrate surface. A preferred spraying the second composition and the third composition and optionally the fourth composition onto the activated substrate surface is a spraying with a two fluid nozzle. Preferably, after contacting the activated substrate surface with the second composition and the third composition and optionally the fourth composition, the non-adhesive layer is removed. A preferred removing the non-adhesive layer is a superimposing the non-adhesive layer with a contact adhesive and stripping of the contact adhesive; or dissolving the non-adhesive layer; or both. A preferred contact adhesive is an adhesive tape.

In another preferred process according to the invention a part of the substrate surface is contacted with a hydrophobing agent. A preferred contacting the part the substrate surface with the hydrophobing agent is a printing or a spraying or both. A preferred printing is one selected from the group consisting of inkjet printing, tampon printing, offset printing, gravure printing and flexographic printing or a combination of at least two thereof. A preferred spraying is a spraying through a mask. A preferred substrate is bendable. Another preferred substrate is not bendable. Preferably, the part of the substrate surface of the bendable substrate is contacted with the hydrophobing agent by one selected from the group consisting of inkjet printing, tampon printing and spraying through a mask or a combination of at least two thereof. Preferably, the part of the substrate surface of the substrate, which is not bendable, is contacted with the hydrophobing agent by one selected from the group consisting of inkjet printing, offset printing, gravure printing, flexographic printing and spraying through a mask or a combination of at least two thereof. Preferably, during contacting the part of the substrate surface with the hydrophobing agent a part of the substrate surface, which is not to be contacted with the hydrophobing agent, is covered by a mask. Preferably, after contacting the part of the substrate surface with the hydrophobing agent, the substrate surface is contacted with the first composition under obtaining the activated substrate surface. A preferred contacting the substrate surface with the first composition is a spraying. Preferably, after contacting the substrate surface with the first composition, the activated substrate surface is contacted with the second composition and the third composition and optionally the fourth composition. A preferred contacting the activated substrate surface with the second composition and the third composition and optionally the fourth composition is a spraying the second composition and the third composition and optionally the fourth composition onto the activated substrate surface. A preferred spraying the second composition and the third composition and optionally the fourth composition onto the activated substrate surface is a spraying with a two fluid nozzle.

In another preferred process according to the invention a part of the substrate surface is hydrophilised. A preferred hydrophilising the part of the substrate surface is a physical hydrophilising; or a contacting the part of the substrate surface with a hydrophilising agent; or both. A preferred physical hydrophilising comprises contacting the part of the substrate surface with a plasma. A preferred substrate is bendable. Another preferred substrate is not bendable. Preferably, the part of the substrate surface of the bendable substrate is contacted with the hydrophilising agent by one selected from the group consisting of inkjet printing, tampon printing and spraying through a mask or a combination of at least two thereof. Preferably, the part of the substrate surface of the substrate, which is not bendable, is contacted with the hydrophilising agent by one selected from the group consisting of inkjet printing, offset printing, gravure printing, flexographic printing and spraying through a mask or a combination of at least two thereof. Preferably, during contacting the part of the substrate surface with the hydrophilising agent or with the plasma or both a part of the substrate surface, which is not to be contacted with the hydrophilising agent or the plasma or both, is covered by a mask. Preferably, after contacting the part of the substrate surface with the hydrophilising agent, the substrate surface is contacted with the first composition under obtaining the activated substrate surface. A preferred contacting the substrate surface with the first composition is a spraying. Preferably, after contacting the substrate surface with the first composition, the activated substrate surface is contacted with the second composition and the third composition and optionally the fourth composition. A preferred contacting the activated substrate surface with the second composition and the third composition and optionally the fourth composition is a spraying the second composition and the third composition and optionally the fourth composition onto the activated substrate surface. A preferred spraying the second composition and the third composition and optionally the fourth composition onto the activated substrate surface is a spraying with a two fluid nozzle.

### Test Methods

The following test methods are used in the invention. In absence of a test method, the ISO test method for the feature to be measured being closest to the earliest filing date of the present application applies. In absence of distinct measuring conditions, standard ambient temperature and pressure (SATP) as a temperature of 298.15 K (25° C., 77° F.) and an absolute pressure of 100 kPa (14.504 psi, 0.986 atm) apply.

### Crystallite Size

In an air conditioned room with a temperature of 22±1° C. equipment and materials are equilibrated prior the measurement. Crystal size measurements were performed using a “STOE Stadi P” from STOE & Cie GmbH, Darmstadt, Germany, equipped with a CuK_{α1} (0.154056 nm) x-ray source, a curved graphite-secondary monochromator, with Bragg-Brentano Geometry equipment (detector: scintillation counter) from STOE), a generator “Bruker-AXS Kris-talloflex 760” (40 kV, 30 mA) and the software “STOE Powder Diffraction Software (win x-pow) Version 2.21” from STOE. This device is applying the x-ray scattering measuring principle. Calibration of the device is in accordance to the NIST-standard Si (lot number: 640d). As reference for the analysis the ICDD database is applied. The sample is placed on a sample holder from Stoe in the middle of the sample holder prior to placing it in the x-ray beam. The sample was measured in reflection mode at 22° C. with following parameters: 2θ: 30-113.01°, ω: 15-56.505°, step: 2θ 0.03°, ω: 0.015°, step time: 10 s, measure time: 8.16 h. Crystal size is determined by the full width at half maximum on the Ag (111) reflex using the software “STOE Powder Diffraction Software (win x-pow), Version 2.21” from STOE.

### Layer Thickness

### Method A:

Method A is used to measure the thickness of the first layer or the further layer if no layer is superimposed on the first layer surface or the further layer surface. In this case the layer thickness can be measured using a profilometer (Tencor, Alphastep 500). The measured layer thickness is the average of three measurements in a laterally limited region of the layer which comprises no substructure.

### Method B:

Method B is used to measure the thickness of the first layer or the further layer if a layer is superimposed on the first layer surface or a further layer surface, comprised by the further layer and facing away from the first layer. In this case the layer sequence comprising the substrate layer and the first layer is first subjected to microtomy. Subsequently, the cut surface of the layer sequence is subjected to a scanning electron microscope. The layer thickness of the first layer or the further layer is determined as the average of three measurements in a laterally limited region of the layer which comprises no substructure.

### Scanning Electron Microscopy SEM

The sample is cut in a way that the area of interest is laid open. In this case perpendicular to the substrate surface so that a cross section of the different layers of the layer sequence comprising the substrate layer and the first layer is obtained. The cut sample is placed in a container filled with embedding material and oriented such that the area of interest is on top. As embedding material, EpoFix (Struers GmbH) is used, mixed according to the instructions. After 8 hours curing at room temperature the sample can be processed further. In a first step the sample is ground with a Labopol-25 (Struers GmbH) using silicon carbide paper 180-800 (Struers GmbH) at 250 rpm. In further steps the sample is polished using a Rotopol-2 equipped with a Retroforce-4, MD Piano 220 and MD allegro cloth and DP-Spray P 3 μm diamond spray (all from Struers GmbH). The examination was performed with a Zeiss Ultra 55 (Carl Zeiss AG), equipped with a field emission electrode, an accelerating voltage of 20 kV and at a pressure of about 3×10⁻⁶ mbar. In some cases the cross sections were used to determine the elemental composition along a line across the different layers and perpendicular to the substrate surface. so called line scan was performed using an EDX measurement (energy dispersive X-ray spectroscopy). A IncaPentaFETx3 attached to the Zeiss Ultra 55 and the software “The Microanalysis Suite Issue 18d+SP3” (both from Oxford Instruments) with an aperture of 30 μm were used.

### Surface Resistivity

The resistivity is a fundamental property of a material. To measure the resistivity of a layer a rectangular or cubical part of the layer is contacted with two electrical contacts at two opposing ends of the rectangle or cube. By applying a known voltage V [V] to the contacts, measuring the current I [A] and knowing the length L [cm], width W [cm] and thickness T [cm] of the tested part of the layer it is possible to calculate the resistivity R×(T×W)/L indicated in [Ω·cm] by using the Ohm's law R=V/I [Ω]. If not specified otherwise the resistivity has been measured by using copper contacts with a contacting surface of 1×1 mm to the opposing ends of the layer to be analysed. A known voltage is applied to the contacts in a range of from 0.01 to 1 V and the current is measured via an amperemeter. The measurement was established at room temperature, normal pressure and a relative humidity of 50%.

### Average Roughness

### Method A:

Method A is used to measure the average roughness of the first layer if no layer is superimposed on the first layer surface. In this case an atomic force microscope is used to determine the average roughness. The average roughness Rₐ is determined in accordance with DIN 4768 in laterally limited regions of the first layer which comprise no substructure.

### Method B:

Method B is used to measure the average roughness of the first layer if a layer is superimposed on the first layer surface. In this case the layer sequence comprising the substrate layer and the first layer is first subjected to microtomy. Subsequently, the cut surface of the layer sequence is subjected to a scanning electron microscope. The average roughness Rₐ of the first layer surface is determined in laterally limited regions of the first layer which comprise no substructure in accordance with DIN 4768.

### Gloss

Measurement of the gloss is performed according to EN ISO 2813:1999 using a device of type GL0030 (TQC Therminport Quality Control GmbH). An angle of incidence/measurement angle of 20° is used. The substrate layer used in the measurements is a glass substrate. The layer thickness after the prescribed heating step is about 0.2 μm. Calibrating the device was performed using the black polished glass plate which comes with the device.

### Substrate Surface Temperature

The surface temperature of the substrate can be measured using the Infra-Red thermometer Testo 845 (Testo AG, Lenzkirch, Germany).

### Width

The width of a protruding region is measured by inspecting the protruding region under an optical microscope in a top view and comparing with a μm-scale. Therein the width is measured as the spatial extend of the protruding region in lateral direction along a straight line.

### EXAMPLES

The present invention is now explained in more detail by examples and drawings given by way of example which do not limit it.

### Example 1 Preparation of Solutions

The subsequent six solutions are prepared using fully de-ionised water with a conductivity of 0.5 μS.

### Solution 1:

In a glass beaker 16 g SnCl₂ (Sigma Aldrich) are dissolved in 9 984 g fully de-ionised water.

### Solution 2:

In a glass beaker 152.1 g Dextrose (Sigma Aldrich), 22.5 g concentrated sulfuric acid (97%; Sigma Aldrich) and 59.4 g formaldehyde solution (37%, Sigma Aldrich) and 766 g fully de-ionised water are mixed.

### Solution 3:

In a glass beaker 265.5 g AgNO₃ (Sigma Aldrich) and 3.7 g Nitric acid (65%, Sigma Aldrich), 297 g Ammonia solution (25%, Sigma Aldrich) and 433.8 g fully de-ionised water are mixed.

### Solution 4:

In a glass beaker 136.6 g NaOH (Sigma Aldrich), 245.7 g Ammonia solution (25%, Sigma Aldrich) and 617.7 g fully de-ionised water are mixed.

### Solution 5:

In a 10 L glass beaker 200 g of Solution 3 and 200 g of Solution 4 are mixed with 9600 g fully de-ionised water.

### Solution 6:

In a 10 L glass beaker 200 g of Solution 2 are mixed with 9800 g fully de-ionsed water

### Example 2

### Spray Coating

A PET substrate is rinsed with water. The substrate is placed in a spraying cabinet. Using a spray gun Solution 1 is sprayed onto the substrate. Subsequently surplus Solution 1 is removed by spraying the substrate with water using the spray gun.

Using a two-component-spray gun (2 k Spray gun) Solution 5 and Solution 6 are mixed in the spray gun and sprayed as a mixture onto the substrate. After several seconds of spraying a silver film appears on the substrate with a typical reflection of metallic silver.

Subsequently the spraying with Solutions 5 and 6 is stopped and the film is rinsed with water to remove the remaining salts.

In order to remove the water the film is dried at 130° C. for 5 Minutes.

The film shows the following properties using the measurement protocols described above:

Film thickness: 35 nm

Surface resistivity: 0.49 Ω/sq

Crystallite size: 30 nm

Gloss: 1627 GU

Average roughness: 35 nm

### Example 3

### Structuring of the Film

The Ag coating on the PET substrate obtained in Example 2 is structured using the following method.

The protection polymer Clevios SET S (Heraeus Precious Metals GmbH &Co KG, Germany) is deposited onto the Ag coating using a silk-screen printer. Subsequently the substrate is subjected to a bath of Chrome Etch 18 (from micro resist technology) for 10-20 seconds at 20° C. Subsequently the substrate is rinsed with water and dried at 100° C. for 2-5 minutes. Protection Polymer SET S is removed by dipping a the film in a 1.25% Ammonia solution for 2 minutes at 25° C. or 30-60° at 40° C. The film is rinsed with water and dried afterwards.

The figures show

1 a flow chart of a process according to the invention;

2 a flow chart of another process according to the invention;

3 a flow chart of another process according to the invention;

4 a flow chart of another process according to the invention;

5 a schematic cross sectional side view of a layer sequence of an electronic composite according to the invention;

6 a schematic cross sectional side view of a layer sequence of another electronic composite according to the invention;

7 a schematic cross sectional side view of a layer sequence of another electronic composite according to the invention;

8 a schematic cross sectional side view of a layer sequence of another electronic composite according to the invention;

9 a schematic cross sectional side view of a layer sequence of another electronic composite according to the invention;

10 a schematic cross sectional side view of a layer sequence according to the invention

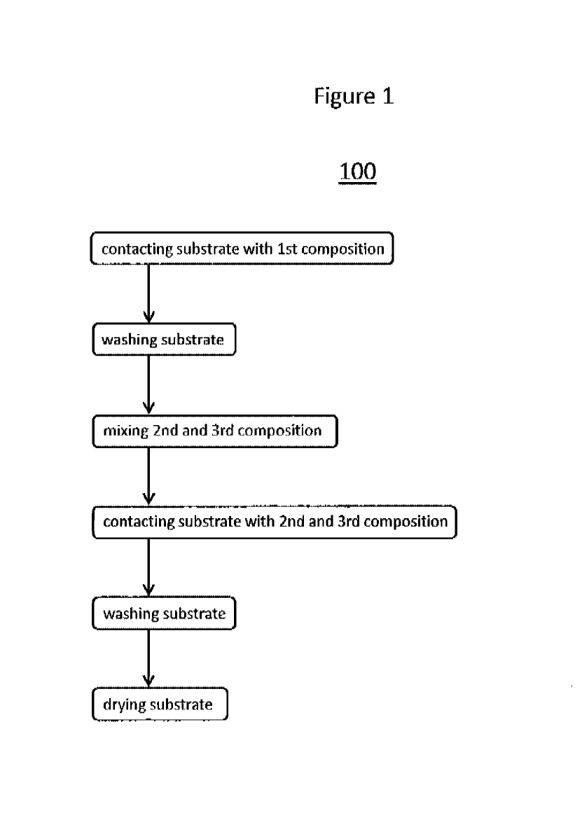

FIG. 1 shows a flow chart of a process 100 according to the invention. The process 100 comprises as process steps providing a substrate having a substrate surface; providing a first composition, comprising: SnCl₂, and water; providing a second composition, comprising: formaldehyde, sulfuric acid, and a poly sugar; providing a third composition, obtainable by mixing: AgNO₃, nitric acid, water, and NH₃; contacting the substrate surface with the first composition under obtaining an activated substrate surface; washing the activated substrate surface with distilled water; mixing the second and the third composition; contacting the activated substrate surface with the second composition and the third composition under obtaining a first layer, having a first layer surface and superimposing the substrate surface, wherein the activated substrate surface has a temperature of 30° C.; washing the substrate surface with distilled water; and drying the substrate and the first layer at 60° C.

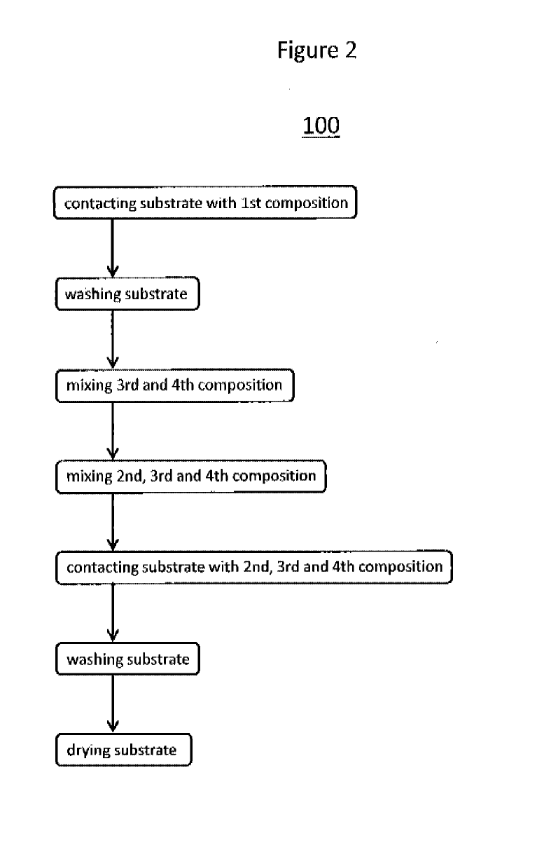

FIG. 2 shows a flow chart of another process 100 according to the invention. The process 100 comprises as a process step providing a substrate having a substrate surface. The substrate comprises PEDOT:PSS. The substrate surface is abraded and polished. Afterwards, the substrate surface is superimposed by a holding primer and a filler. Afterwards, the substrate surface is superimposed by a two component acrylic varnish under obtaining an acrylic varnish layer which superimposes the substrate surface. The acrylic varnish layer comprises an acrylic varnish layer surface. The acrylic varnish layer surface is polished with an abrasive having a grain size of 1200. Preferably, the acrylic varnish layer works as an adhesion promoter. Preferably, the acrylic varnish layer prevents a degassing of the substrate or a plasticiser migration or both. The acrylic varnish layer has a thickness in a range from 20 to 30 μm. The acrylic varnish layer is dried for 2 to 5 hours at 60° C. Next process steps are providing a first composition; providing a second composition; providing a third composition; and providing a fourth composition. The first composition comprises SnCl₂ in an amount of 0.16 wt.-%, and distilled water in an amount of 99.84 wt.-%, each based on the total weight of the first composition. The second composition comprises dextrose in an amount of 72.38 wt.-%, sulfuric acid in an amount of 19.12 wt.-%, and formaldehyde in an amount of 8.5 wt.-%, each based on the weight of the second composition excluding water. The second composition further comprises 600 ml of distilled water. The second composition is filled up to a total volume of 1 l with distilled water under obtaining a second working solution. The third composition comprises Ag—NO₃ in an amount of 98.63 wt.-%, nitric acid in an amount of 1.35 wt.-%, and NH₃ in an amount of 0.02 wt.-%, each based on the weight of the third composition excluding water. The third composition further comprises 400 ml of distilled water. The third composition is filled up to a total volume of 1 l with distilled water under obtaining a third working solution. The fourth composition comprises NaOH in an amount of 99.97 wt.-%, and NH₃ in an amount of 0.03 wt.-%, each based on the weight of the fourth composition excluding water. The fourth composition further comprises 500 ml of distilled water. The fourth composition is filled up to a total volume of 1 l with distilled water under obtaining a fourth working solution. Next process steps comprise spraying the substrate surface with the first composition under obtaining an activated substrate surface; washing the activated substrate surface with distilled water; mixing the third working solution, comprising the third composition, and the fourth working solution, comprising the fourth composition; spraying a mixture of the third working solution and the fourth working solution as a first fluid, and the second working solution, comprising the second composition, as a second fluid with a multi-fluid nozzle onto the activated substrate surface. Therein the multi-fluid nozzle mixes the mixture of the third working solution and the fourth working solution with the second working solution outside of the multi-fluid nozzle. Thereby, a first layer, superimposing the substrate surface, is obtained. The first layer comprises Ag. During spraying the mixture of the third working solution and the fourth working solution as the first fluid, and the second working solution as the second fluid with a multi-fluid nozzle onto the activated substrate surface the activated substrate surface has a temperature of 25° C. Next process steps comprise washing the substrate surface with distilled water; and drying the substrate and the first layer at 60° C.

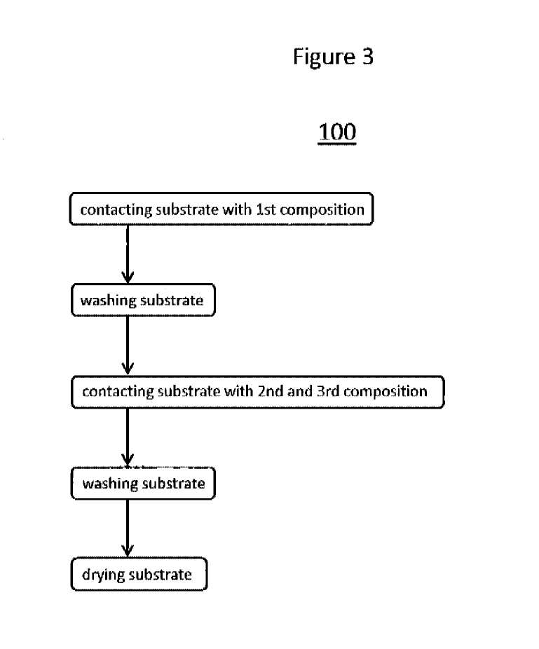

FIG. 3 shows a flow chart of another process 100 according to the invention. The process 100 comprises as a process step providing a substrate having a substrate surface. The substrate is an ABS plastic substrate. The substrate surface is abraded and polished. Afterwards, the substrate surface is superimposed by a holding primer and a filler. Afterwards, the substrate surface is superimposed by a two component acrylic varnish under obtaining an acrylic varnish layer which superimposes the substrate surface. The acrylic varnish layer comprises an acrylic varnish layer surface. The acrylic varnish layer surface is polished with an abrasive having a grain size of 1200. Preferably, the acrylic varnish layer works as an adhesion promoter. Preferably, the acrylic varnish layer prevents a degassing of the substrate or a plasticiser migration or both. The acrylic varnish layer has a thickness in a range from 20 to 30 μm. The acrylic varnish layer is dried for 2 to 5 hours at 60° C. Next process steps are providing a first composition; providing a second composition; and providing a third composition. The first composition comprises SnCl₂ in an amount of 0.16 wt.-%, and distilled water in an amount of 99.84 wt.-%, each based on the total weight of the first composition. The second composition comprises dextrose in an amount of 72.38 wt.-%, sulfuric acid in an amount of 19.12 wt.-%, and formaldehyde in an amount of 8.5 wt.-%, each based on the weight of the second composition excluding water. The second composition further comprises 600 ml of distilled water. The second composition is filled up to a total volume of 1 l with distilled water under obtaining a second working solution. The third composition comprises AgNO₃ in an amount of 98.63 wt.-%, nitric acid in an amount of 1.35 wt.-%, and NH₃ in an amount of 0.02 wt.-%, each based on the weight of the third composition excluding water. The third composition further comprises 400 ml of distilled water. The third composition is filled up to a total volume of 1 l with distilled water under obtaining a third working solution. Next process steps comprise spraying the substrate surface with the first composition under obtaining an activated substrate surface; washing the activated substrate surface with distilled water; simultaneously spraying the second working solution, comprising the second composition, and the third working solution, comprising the second composition, onto the activated substrate surface. Thereby, a first layer superimposing the substrate surface is obtained. The first layer comprises Ag. During spraying the second working solution and the third working solution onto the activated substrate surface the activated substrate surface has a temperature of 25° C. Next process steps comprise washing the substrate surface with distilled water; and drying the substrate and the first layer at 60° C.

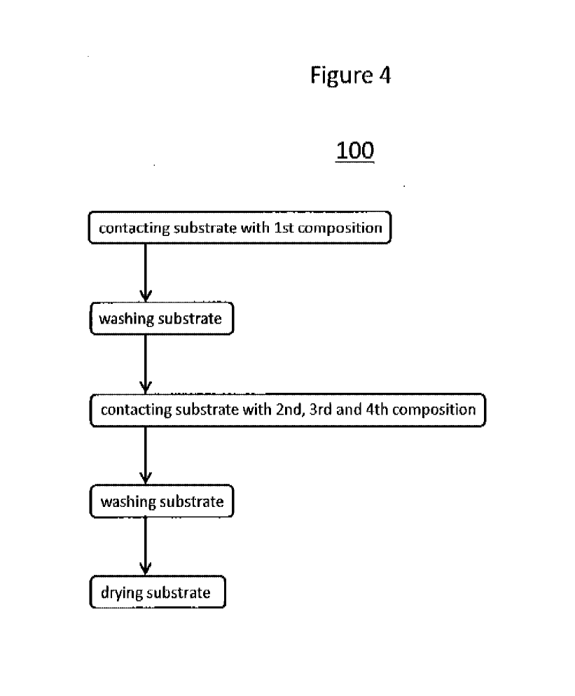

FIG. 4 shows a flow chart of another process 100 according to the invention. The process 100 comprises as a process step providing a substrate having a substrate surface. The substrate is an ABS plastic substrate. The substrate surface is abraded and polished. Afterwards, the substrate surface is superimposed by a holding primer and a filler. Afterwards, the substrate surface is superimposed by a two component acrylic varnish under obtaining an acrylic varnish layer which superimposes the substrate surface. The acrylic varnish layer comprises an acrylic varnish layer surface. The acrylic varnish layer surface is polished with an abrasive having a grain size of 1200. Preferably, the acrylic varnish layer works as an adhesion promoter. Preferably, the acrylic varnish layer prevents a degassing of the substrate or a plasticiser migration or both. The acrylic varnish layer has a thickness in a range from 20 to 30 μm. The acrylic varnish layer is dried for 2 to 5 hours at 60° C. Next process steps are providing a first composition; providing a second composition; providing a third composition; and providing a fourth composition. The first composition comprises SnCl₂ in an amount of 0.16 wt.-%, and distilled water in an amount of 99.84 wt.-%, each based on the total weight of the first composition. The second composition comprises dextrose in an amount of 72.38 wt.-%, sulfuric acid in an amount of 19.12 wt.-%, and formaldehyde in an amount of 8.5 wt.-%, each based on the weight of the second composition excluding water. The second composition further comprises 600 ml of distilled water. The second composition is filled up to a total volume of 1 l with distilled water under obtaining a second working solution. The third composition comprises Ag—NO₃ in an amount of 98.63 wt.-%, nitric acid in an amount of 1.35 wt.-%, and NH₃ in an amount of 0.02 wt.-%, each based on the weight of the third composition excluding water. The third composition further comprises 400 ml of distilled water. The third composition is filled up to a total volume of 1 l with distilled water under obtaining a third working solution. The fourth composition comprises NaOH in an amount of 99.97 wt.-%, and NH₃ in an amount of 0.03 wt.-%, each based on the weight of the fourth composition excluding water. The fourth composition further comprises 500 ml of distilled water. The fourth composition is filled up to a total volume of 1 l with distilled water under obtaining a fourth working solution. Next process steps comprise spraying the substrate surface with the first composition under obtaining an activated substrate surface; washing the activated substrate surface with distilled water; simultaneously spraying the second working solution, comprising the second composition; the third working solution, comprising the third composition; and the fourth working solution, comprising the fourth composition, onto the activated substrate surface. Thereby, a first layer, superimposing the substrate surface, is obtained. The first layer comprises Ag. During spraying the second working solution, the third working solution, and the fourth working solution onto the activated substrate surface the activated substrate surface has a temperature of 25° C. Next process steps comprise washing the substrate surface with distilled water; and drying the substrate and the first layer at 60° C.

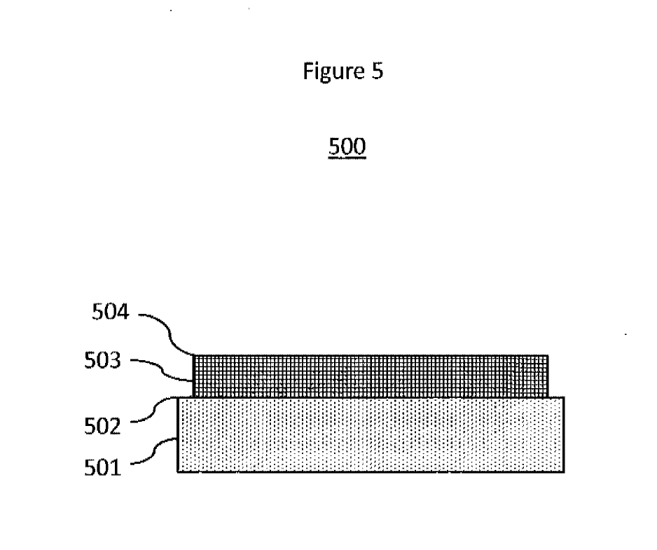

FIG. 5 shows a schematic cross sectional side view of a layer sequence 500 of an electronic composite according to the invention. The layer sequence 500 comprises a substrate 501 having a substrate surface 502, and a first layer 503 having a first layer surface 504. The first layer 503 superimposes the substrate surface 502. The substrate 501 comprises polyester. The first layer 503 comprises crystallites having crystallite sizes in a range from 80 to 100 nm. The first layer 503 has a layer thickness of 300 nm. The electronic composite is a touch screen.

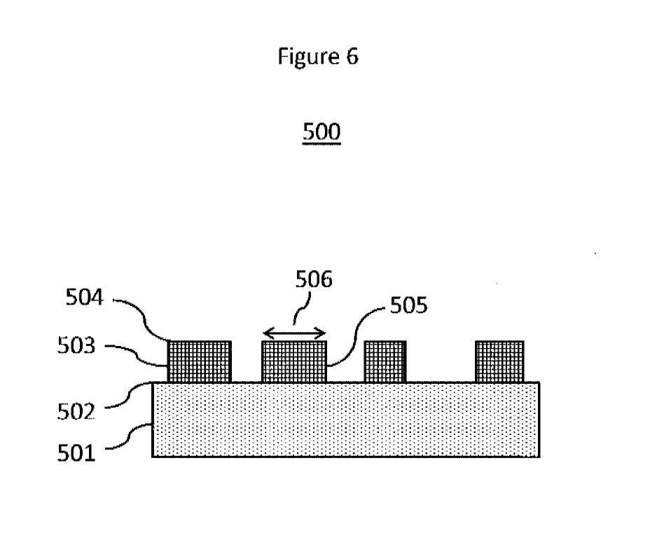

FIG. 6 shows a schematic cross sectional side view of another layer sequence 500 of an electronic composite according to the invention. The layer sequence 500 comprises a substrate 501 having a substrate surface 502, and a first layer 503 having a first layer surface 504. The first layer 503 superimposes the substrate surface 502. The substrate 501 comprises polyester.

The first layer 503 comprises crystallites having crystallite sizes in a range from 80 to 100 nm. The first layer 503 has a layer thickness of 300 nm. The first layer 503 is a relief which comprises protruding regions 505. The protruding regions 505 are conducting paths 505. A width 506 of the conducting paths 505 is 40 μm. The electronic composite is a touch screen.

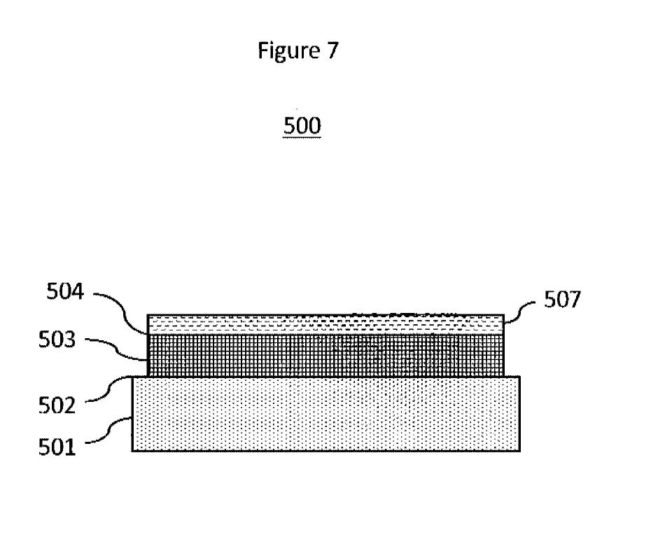

FIG. 7 shows a schematic cross sectional side view of another layer sequence 500 of an electronic composite according to the invention. The layer sequence 500 comprises a substrate 501 having a substrate surface 502, a first layer 503 having a first layer surface 504, and a further layer 507. The first layer 503 superimposes the substrate surface 502. The further layer 507 superimposes the first layer surface 504. The substrate 501 comprises polyester. The first layer 503 comprises crystallites having crystallite sizes in a range from 80 to 100 nm. The first layer 503 has a layer thickness of 300 nm. The further layer 507 is transparent and electrically conductive. The further layer 507 comprises PEDOT:PSS. The further layer 507 has a layer thickness of 90 μm. The electronic composite is a photovoltaic cell.

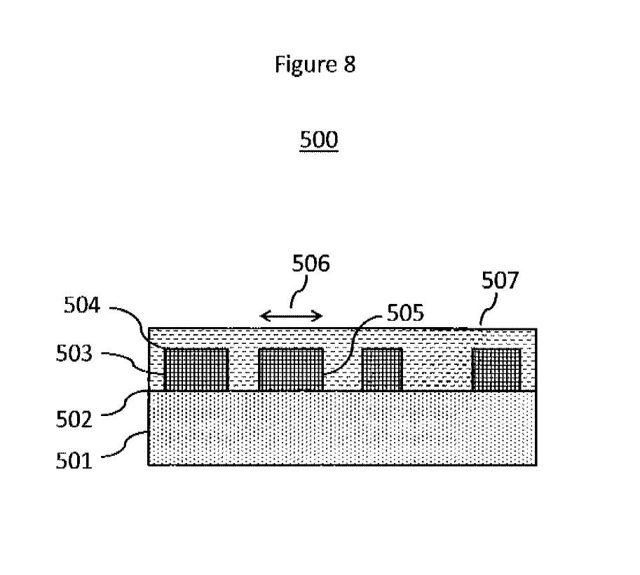

FIG. 8 shows a schematic cross sectional side view of the layer sequence 500 in FIG. 6, wherein the layer sequence 500 further comprises a further layer 507. The further layer 507 superimposes the first layer surface 504. Moreover, the first layer 503 is embedded in the further layer 507. The further layer 507 is transparent and electrically conductive. The further layer 507 comprises PEDOT:PSS. The further layer 507 has a layer thickness of 250 μm.

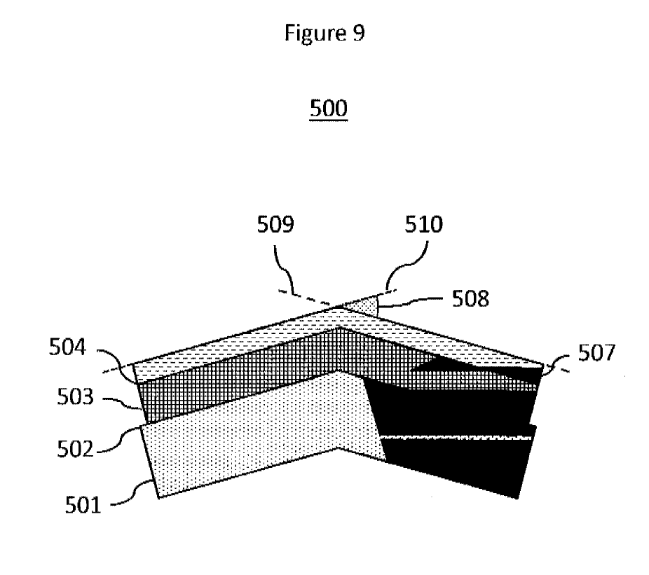

FIG. 9 shows a schematic cross sectional side view of the layer sequence 500 in FIG. 7. The layer sequence 500 is bendable. The angle 508 between a first tangent 509 on a surface of the further layer 507 and a further tangent 510 on the surface of the further layer 507 can be mechanically varied by at least 15° without destroying any layer of the layer sequence 500.

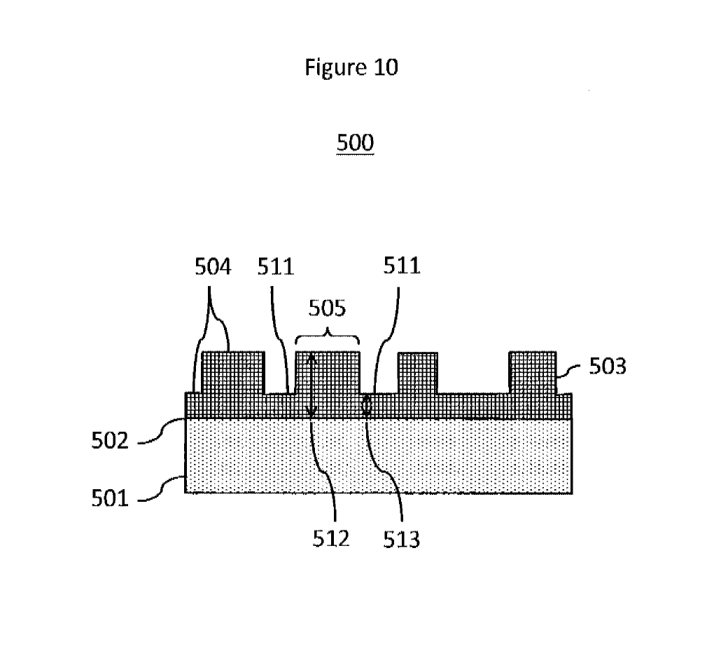

FIG. 10 shows a schematic cross sectional side view of another layer sequence 500 according to the invention. The layer sequence 500 comprises a substrate 501 having a substrate surface 502, and a first layer 503 having a first layer surface 504. The first layer 503 superimposes the substrate surface 502. The first layer 503 comprises crystallites having crystallite sizes in a range from 80 to 100 nm. The first layer 503 is a relief which comprises protruding regions 505. The protruding regions 505 are laterally limited regions 505 of the first layer 503. Therein the laterally limited regions 505 have thicknesses 512 which are at least twice as high as a highest thickness 513 of regions adjacent to the laterally limited region 511.

### LIST OF REFERENCES

100 process according to the invention
500 layer sequence according to the invention
501 substrate
502 substrate surface
503 first layer
504 first layer surface
505 protruding region/laterally limited region
506 width
507 further layer
508 angle
509 first tangent
510 further tangent
511 region adjacent to laterally limited region
512 thickness of laterally limited region
513 thickness of region adjacent to laterally limited region

1. A process (100) comprising as process steps:
a) providing a substrate having a substrate surface;
b) providing a first composition, comprising:
i) SnCl₂, and
ii) water;
c) providing a second composition, comprising:
i) sulfuric acid, and
ii) a reducing agent;
d) providing a third composition, obtainable by mixing:
i) AgNO₃,
ii) nitric acid,
iii) water, and
iv) NH₃;
e) contacting the substrate surface with the first composition under obtaining an activated substrate surface;
f) contacting the activated substrate surface with the second composition and the third composition, wherein the activated substrate surface has a temperature in a range from about 10 to about 50° C.

2. The process (100) according to claim 1, wherein the reducing agent is a sugar.

3. The process (100) according to claim 1, wherein the first composition comprises Ag in a range of less than 1 wt.-% based on the total weight of the first composition.

4. The process (100) according to claim 1, wherein
a) the process (100) comprises as a further process step, providing a fourth composition, comprising
i) NaOH,
ii) NH₃, and
iii) water; and
b) the process step f) further comprises contacting the activated substrate surface with the fourth composition.

5. The process (100) according to claim 4, wherein before contacting the substrate surface with the second composition, the third composition and the fourth composition;
the third composition and the fourth composition are mixed.

6. The process (100) according to claim 1, wherein one selected from the group consisting of the first composition, the second composition, and the third composition or a combination of at least two thereof comprises further cations other than the present cations of each of the group consisting of Sn, Na and Ag in a range of less than 1 ppmw based on the total weight of the composition characterised by this feature.

7. The process (100) according to claim 1, wherein less than 30 s before contacting the substrate surface with the second composition and the third composition; the second composition and the third composition are mixed.

8. The process (100) according to claim 1, wherein the substrate comprises one selected from the group consisting of a polymer, a ceramic, a semiconductor, a stone and a glass or a combination of at least two thereof.

9. The process (100) according to claim 8, wherein the polymer is one selected from the group consisting of a polyimide, a polyester, PEDOT:PSS, polyacetylene, polyphenylene vinylene, polypyrrole, polythiophene, polyaniline and polyphenylene sulfide or a combination of at least two thereof.

10. The process (100) according to claim 1, wherein a first layer is obtained by the process (100),
wherein the first layer
a) superimposes the substrate surface,
b) comprises Ag, and
c) comprises a first layer surface,
wherein the first layer has a layer thickness which is described by a non-constant function of the position on the substrate surface.

11. The process (100) according to claim 10, wherein the first layer has a layer thickness in a range from about 10 nm to about 100 μm.

12. The process (100) according to claim 10, wherein the first layer comprises a protruding region having a width in a range from about 5 to about 100 μm.

13. The process (100) according to claim 10, wherein a further process step comprises superimposing the first layer surface by a further layer,
wherein the further layer is electrically conductive or transparent or both.

14. The process (100) according to claim 13, wherein the further layer comprises an electrically conductive polymer.

15. The process (100) according to claim 1, wherein the first composition comprises
a) SnCl₂ in a range from about 0.01 to about 1 wt.-%, and
b) water in a range from about 90 wt.-% to the remainder completing the sum of all components of the first composition to 100 wt.-%,
each based on the total weight of the first composition and all contents in wt.-% adding to 100 wt.-%.

16. The process (100) according to claim 1, wherein the second composition comprises
a) dextrose in a range from about 60 wt.-% to the remainder completing the sum of all components of the second composition to 100 wt.-%,
b) sulfuric acid in a range from about 10 to about 30 wt.-%, and
c) formaldehyde in a range from about 3 to about 15 wt.-%,
each based on the weight of the second composition excluding water and all contents in wt.-% adding to 100 wt.-%.

17. The process (100) according to claim 1, wherein the third composition is obtainable by mixing
a) AgNO₃ in a range from about 95 wt.-% to the remainder completing the sum of all components of the third composition to 100 wt.-%,
b) nitric acid in a range from about 0.5 to about 5 wt.-%, and
c) NH₃ in a range from about 0.01 to about 0.1 wt.-%,
each based on the weight of the third composition excluding water and all contents in wt.-% adding to 100 wt.-%.

18. The process (100) according to claim 4, wherein the fourth composition comprises
a) NaOH in a range from about 99 wt.-% to the remainder completing the sum of all components of the fourth composition to 100 wt.-%, and
b) NH₃ in a range from about 0.01 to about 1 wt.-%,
each based on the weight of the fourth composition excluding water and all contents in wt.-% adding to 100 wt.-%.

19. A composite obtainable by the process (100) according to claim 1.

20. A composite, comprising a layer sequence (500),
wherein the layer sequence (500) comprises as layers:
a) a substrate (501) having a substrate surface (502);
b) a first layer (503) having a first layer surface (504),
wherein the first layer (503)
i) superimposes the substrate surface (502),
ii) comprises Ag,
iii) fulfils at least one of the following criteria
A. the first layer (503) comprises a crystallite having a crystallite size in a range from about 10 to about 160 nm,
B. the first layer (503) has a surface resistivity of less than 10 Ω/sq,
C. the first layer (503) has a layer thickness in a range from about 10 nm to about 10 μm,
D. the first layer (503) has a gloss in a range from about 500 to about 2000 GU, and
E. the first layer (503) has an average roughness in a range from about 1 to about 500 nm,
or a combination of at least two or more thereof.

21. The composite according to claim 20, wherein the layer sequence (500) comprises a further layer (507),
wherein the further layer (507) superimposes the first layer surface (504),
wherein the further layer (507) is transparent or electrically conductive or both.

22. The composite according to claim 21, wherein the further layer (507) comprises an electrically conductive polymer.

23. The composite according to claim 21, wherein the further layer (507) has a layer thickness in a range from about 50 to about 350 nm.

24. The composite according to claim 20, wherein the first layer (503) has a layer thickness which is described by a non-constant function of the position on the substrate surface (502).

25. The composite according to claim 24, wherein the first layer (503) comprises a protruding region (505) having a width (506) in a range from about 5 to about 100 μm.

26. A composition obtainable by mixing
a) an aldehyde,
b) sulfuric acid,
c) a further organic compound,
d) AgNO₃,
e) nitric acid,
f) water,
g) NH3, and
h) NaOH.
